(19) United States
(12) Patent Application Publication
(10) Pub. No.: US 2016/0204240 A1
(43) Pub. Date: Jul. 14, 2016

(54) POWER SEMICONDUCTOR DEVICE

(71) Applicant: ABB Technology AG, Zürich (CH)

(72) Inventor: Friedhelm Bauer, Semione (CH)

(21) Appl. No.: 15/075,766

(22) Filed: Mar. 21, 2016

Related U.S. Application Data
(63) Continuation of application No. PCT/EP2014/070082, filed on Sep. 22, 2014.

(30) Foreign Application Priority Data
Sep. 20, 2013 (EP) 13185374.9

(51) Int. Cl. H01L 29/745; H01L 29/417; H01L 29/10; H01L 29/08

(52) U.S. Cl. CPC H01L 29/7455; H01L 29/0834; H01L 29/41716; H01L 29/1095; H01L 29/1012; H01L 29/0839; H01L 29/0847

(57) ABSTRACT

A power semiconductor device is provided comprising: a collector electrode, a collector layer of a second conductivity type, a drift layer of a first conductivity type, a base layer of the second conductivity type, a first insulating layer having an opening, an emitter layer of the first conductivity type, the emitter layer contacts the base layer and separated from the drift layer by one of the first insulating layer or the base layer, a body layer of the second conductivity type arranged laterally to the emitter layer and separated from the base layer by the first insulating layer and the emitter layer, a source region of the first conductivity type separated from the emitter layer by the body layer, an emitter electrode contacted by the source region. The device further comprises a first layer of the second conductivity type contacting the emitter electrode and separated from the base layer, and a second layer of the first conductivity type arranged between the first layer and the base layer and separated from the emitter layer and the source region. A planar MIS gate electrode is arranged laterally from the emitter electrode, a corresponding MIS channel being formable between the source region, the body layer and the emitter layer. A thyristor current path extends between the emitter layer, the base layer and the drift layer through the opening, and a turn-off MIS channel is formable below the planar MIS gate electrode from the first layer, the second layer, the base layer to the drift layer.

### TECHNICAL FIELD

The invention relates to the field of power electronics and more particularly to a power semiconductor device.

### BACKGROUND ART

### Modes for Carrying Out the Invention

In FIG. 1 a cross sectional view of an emitter switched thyristor (EST) is shown, which comprises a wafer 10 having an emitter side 17 and a collector side 12, on which sides an emitter electrode 15 and a collector electrode 1 are arranged. On the emitter side 17, a planar gate electrode 9 is arranged, which comprises an electrically conductive gate layer 92, an electrically conductive further gate layer 93 and a second insulating layer 94, which insulates the gate layers 92 and 93 from any layer of the first or second conductivity type in the wafer 10 and from each other.

Like in an IGBT, on the emitter side 17, an n+ doped source region 7, which extends to a region below the gate layer 91 and a p doped base layer 4 surrounding the source region 7 are arranged. The source region 7 and the base layer 4 contact the emitter electrode 15 at an emitter contact area 18. The device further comprises on the emitter side 17 a further n+ doped source region 72, which is insulated from the emitter electrode 15 by the second insulating layer 94. The further source region 72 extends from a region below the gate layer 91 to a region below a further gate layer 93, which completely surrounds the gate layer 91. Towards the collector electrode 1, a lowly (n−) doped drift layer 3 and a p doped collector layer 2 are arranged.

In this device, a MOS channel 100 is formable form the source region 7 via the base layer 4 to the further source region 72. In the device, another channel in form of a thyristor current path 105 is formable during operation from the further source region 72 via the base layer 4 to the drift layer 3. Another thyristor current path is formable from the base layer 4, through the drift layer 3 to the collector layer 2.

The EST uses a cascade concept, in which a low voltage MOSFET is integrated in series with a thyristor structure, such that by turning off the MOSFET, the thyristor is turned off. Due to the shorted base layer the EST provides a MOS voltage controlled turn-on switching, a higher safe operating area and handling fault conditions when compared to the IGCT. Such a device has limited short circuit capability depending on its low voltage MOSFET blocking and higher on-state snapback effects.

Also the on-state losses are higher due to the low voltage MOSFET channel 100 resistance than for a prior art IGCT. The base layer 4 is shorted in the EST devices, so that the thyristor structure enhancement effect is reduced due to hole drainage, and hence this results in higher on-state losses. The holes generated in the collector layer 2 may be directly catched in the base layer 4 and can, therefore not contribute to electron injection in the source regions 7. The on-state suffers from a snap-back effect before the thyristor areas are latched since conduction occurs initially through the two channels.

U.S. Pat. No. 6,169,299 B1 shows an IGBT having insulating layers embedded in a p doped base layer. A source region is separated from an emitter region by a floating p body layer. A MOS channel is formed below a planar gate electrode from the source region, through the body layer to the emitter layer. A first thyristor channel is formed from the emitter layer through an opening in the insulating layer and the base layer to the drift layer.

U.S. Pat. No. 5,291,040 A shows a thyristor having an n source region surrounded by a floating p body layer, which is laterally terminated by another n doped layer. Within the p body layer an insulating layer is arranged, which separates the body layer in two regions. Another p doped region, which is connected to the emitter electrode forms a turn-off channel from the p base layer to the emitter electrode. The device needs two different gates.

### DISCLOSURE OF INVENTION

It is an object of the invention to provide a power semiconductor device, which avoids any loss of holes by a hole drainage effect when conducting current in the on-state.

This object is achieved by providing a power semiconductor device comprising at least a four-layer structure with layers of a first and second conductivity type, which is different from the first conductivity type, said structure comprising layers in the following order:
a collector electrode,
a collector layer of a second conductivity type,
a drift layer of a first conductivity type,
a base layer of the second conductivity type,
a first insulating layer having an opening,
an emitter layer of the first conductivity type, wherein the emitter layer is in contact to the base layer and wherein the emitter layer is separated from the drift layer at least by one of the first insulating layer or the base layer,
a body layer of the second conductivity type, which is arranged laterally to the emitter layer and which body layer is separated from the base layer by the first insulating layer and the emitter layer,
a source region of the first conductivity type, which is separated from the emitter layer by the body layer,
an emitter electrode, which is at least contacted by the source region at an emitter contact area.

The device further comprises a p doped first layer, which is in contact to the emitter electrode and separated from the base layer and an n doped second layer, which is arranged between the first layer and the base layer and which is separated from the emitter layer and the source region.

A planar gate electrode is arranged laterally from the emitter electrode, which planar gate electrode comprises an electrically conductive gate layer and a second insulating layer, which insulates the gate layer from any layer of the first or second conductivity type and from the emitter electrode.

A MIS channel is formable between the source region, the body layer and the emitter layer. A first thyristor current path is formable between the emitter layer, the base layer and the drift layer through the opening and a second thyristor current path is formable between the base layer, the drift layer and the collector layer.

A turn-off channel is formable below the planar gate electrode from the first layer, the second layer, the base layer to the drift layer.

Due to the presence of the first insulating layer, no holes generated in the collector layer can flow into the p body layer and escape from recombination in the emitter layer, i.e. hole drainage effect is avoided. All holes flow into the emitter layer, which again generates a high electron injection. Therefore, conduction losses are very low in this device. Advantageously, the emitter layer is highly doped with a doping concentration up to 10²⁰ cm⁻³, so that the holes can efficiently be destroyed in the emitter layer, which again makes it possible to achieve high current amplification.

The avoidance of hole drainage together with the current amplification allow a high plasma concentration at the emitter, so that the collector layer may be comparatively low doped, exemplarily with a maximum doping concentration between 1*10¹⁶ up to 1*10¹⁹ cm⁻³. Thus, the plasma concentration is higher on the emitter side, which again allows obtaining very low turn-off switching losses during hard inductive switching.

The device does not need any highly doped enhancement layer of the first conductivity type, which is arranged in prior art devices between the drift layer and the base layer in order to reduce hole drainage effect. However, due to the presence of such enhancement layers, high electric fields are generated in prior art devices during blocking or turn-off with a likelihood of high failure rates due to cosmic rays. As the present invention avoids the presence of a higher doped layer of the first conductivity type between the drift layer and the base layer, the inventive device has lower cosmic ray induced failure rates, which allows operating at higher blocking voltages.

### BRIEF DESCRIPTION OF DRAWINGS

The subject matter of the invention will be explained in more detail in the following text with reference to the attached drawings, in which:

FIG. 1 shows a prior art EST device;

FIG. 2 shows an n MIS channel for a semiconductor device according to the invention, in which the body layer is separated from the emitter electrode by the source region;

FIG. 3 shows another n MIS channel for a semiconductor device according to the invention in which the body layer has contact to the emitter electrode;

FIG. 4 shows another n MIS channel for a semiconductor device according to the invention in which the source region extends to the first insulating layer;

FIG. 5-9 show a p MIS channel for a semiconductor device according to the invention, which comprise an integrated hole path channel;

FIG. 10 shows another semiconductor device according to the invention, which comprises an integrated turn-on channel;

FIG. 11 shows a separate turn-on channel for a semiconductor device according to the invention, which comprises a separate turn-on channel; and

FIG. 12 shows another n MIS channel for a semiconductor device according to the invention, in which the body layer is separated from the emitter electrode by the source region and which comprises a body contact layer.

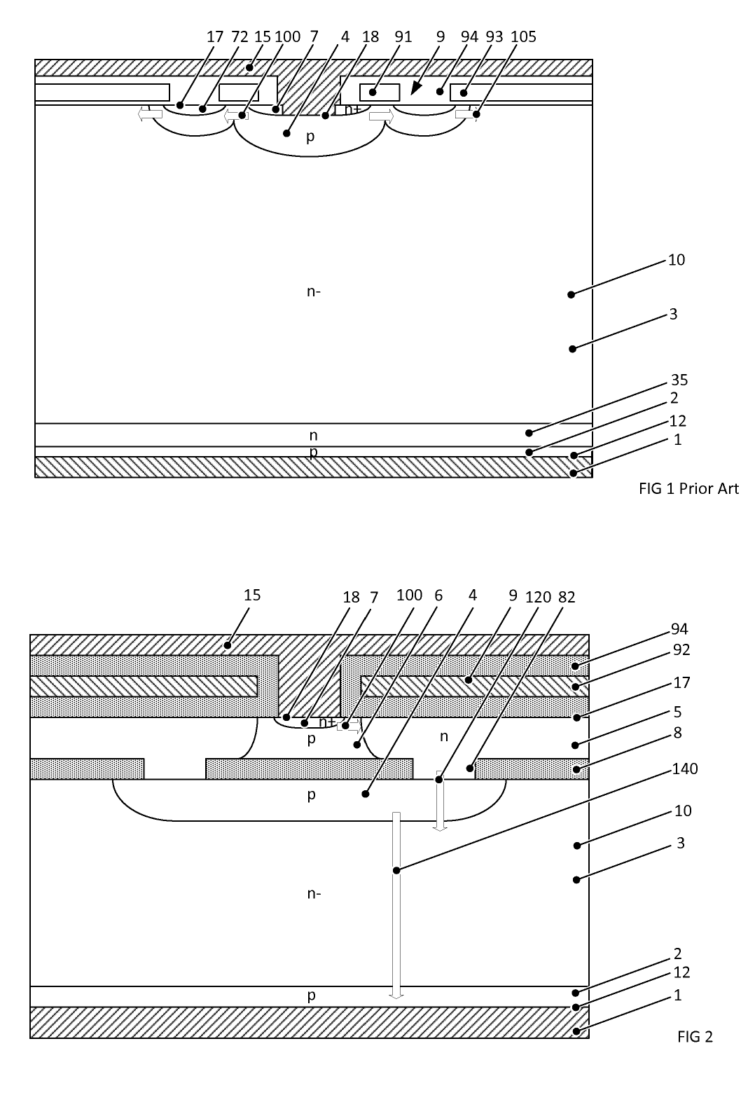

The reference symbols used in the figures and their meaning are summarized in the list of reference symbols. Generally, alike or alike-functioning parts are given the same reference symbols. The described embodiments are meant as examples and shall not confine the invention.

### MODES FOR CARRYING OUT THE INVENTION

An inventive power semiconductor device as shown in FIG. 2 having at least a four-layer structure with layers of a first and second conductivity type, which is different from the first conductivity type, comprises a wafer 10, on which wafer 10 an emitter electrode 15 is arranged on an emitter side 17 of the wafer and a collector electrode 1 is arranged on a collector side 12 of the wafer opposite to the emitter side 17.

The wafer comprises n and p doped layers between the collector side 12 and the emitter side 17. The device comprises, in the following order:
a p doped collector layer 2,
a constantly low (n−) doped drift layer 3,
a p doped base layer 4,
a first insulating layer 8 having an opening (through-hole) 82,
a highly n doped emitter layer 5, which has a higher maximum doping concentration than the drift layer 3, wherein the emitter layer 5 is in contact to the base layer 4 at the opening 82, and wherein the emitter layer 5 is separated from the drift layer 3 by the first insulating layer 8 and the base layer 4,
a p doped body layer 6, which is arranged laterally to the emitter layer 5 and which body layer 6 is separated from the base layer 4 by the first insulating layer 8 and the emitter layer 5,
a source region 7 of the first conductivity type, which is separated from the emitter layer 5 by the body layer 6, wherein the source region 7 is in contact to the emitter electrode 15 at an emitter contact area 18.

A planar gate electrode 9 is arranged laterally from the emitter contact area 18, at which the emitter electrode 15 contacts the source region 7 on the emitter side 17 and, optionally, other doped layers. Laterally shall mean that two layers are arranged in the same plane, which plane is arranged parallel to the emitter side 17. The layers shall either be in the same plane or at least the layers shall overlap in a plane parallel to the emitter side 17. The planar gate electrode 9 comprises an electrically conductive gate layer 92 and a second insulating layer 94, which insulates the gate layer 92 from any n or p type layer in the wafer 10 extending to the emitter sided surface of the wafer 10 in an area below the gate layer 92 and from the emitter electrode 15. The electrically conductive layer 92 extends to an area above the base layer 4 and the emitter layer 5. The second insulating layer 94 may comprise a first insulating region, in which the gate layer 92 is arranged above the second insulating layer 94, i.e. the first insulating region is arranged between the gate layer 92 and the wafer, and a second insulating region, which is arranged on top of the gate layer 92 (on the side facing the emitter electrode 15) and thus, the gate layer 92 is arranged above the second insulating layer 94 in this region. The first insulating region may have a thickness of 0.05 to 0.2 μm. Exemplarily, the second insulating region has a thickness of 0.2 to 3 μm.

The second insulating layer may be made of an insulating material, wherein also a dielectricum like a metal oxide shall be considered as an insulating layer. In case of the insulating layer being a metal oxide layer the channel described below may also be called a MOS channel (metal oxide semiconductor), whereas otherwise the channel may be called MIS channel (metal insulator semiconductor). These channels may also be called electric field induced inversion channel. As a material for the gate layer 92 any appropriate electrically conductive material like a metal or polysilicon may be used.

The device further comprises a p doped first layer 65, which is in contact to the emitter electrode 15 and separated from the base layer 4 and an n doped second layer 55, which is arranged between the first layer 65 and the base layer 4 and which is separated from the emitter layer 5 and the source region 7. The first layer 65 is separated from the base layer 4 by the first insulating layer 8 and the emitter layer 5. The second layer 55 is separated from the source region 7 (if a source region 7 is present at the same emitter electrode contact area) by the body layer 6. If the first layer 65 extends to the first insulating layer 8, also the first layer 65 separates the second layer 55 from the source region 7. The second layer 55 is separated from the emitter layer 5 at least by the first insulating layer 8 and the body layer 6.

Different current paths are formable in the device. An n-MIS channel 100 is formable between the source region 7, the body layer 6 and the emitter layer 5. A first thyristor current path 120 is formable between the emitter layer 5, the base layer 4 and the drift layer 3 through the opening 82. A second thyristor current path 140 is formable between the base layer 4, the drift layer 3 and the collector layer 2.

A turn-off channel 110 is formable below the planar gate electrode 9 from the first layer 65, the second layer 55, the base layer 4 to the drift layer 3.

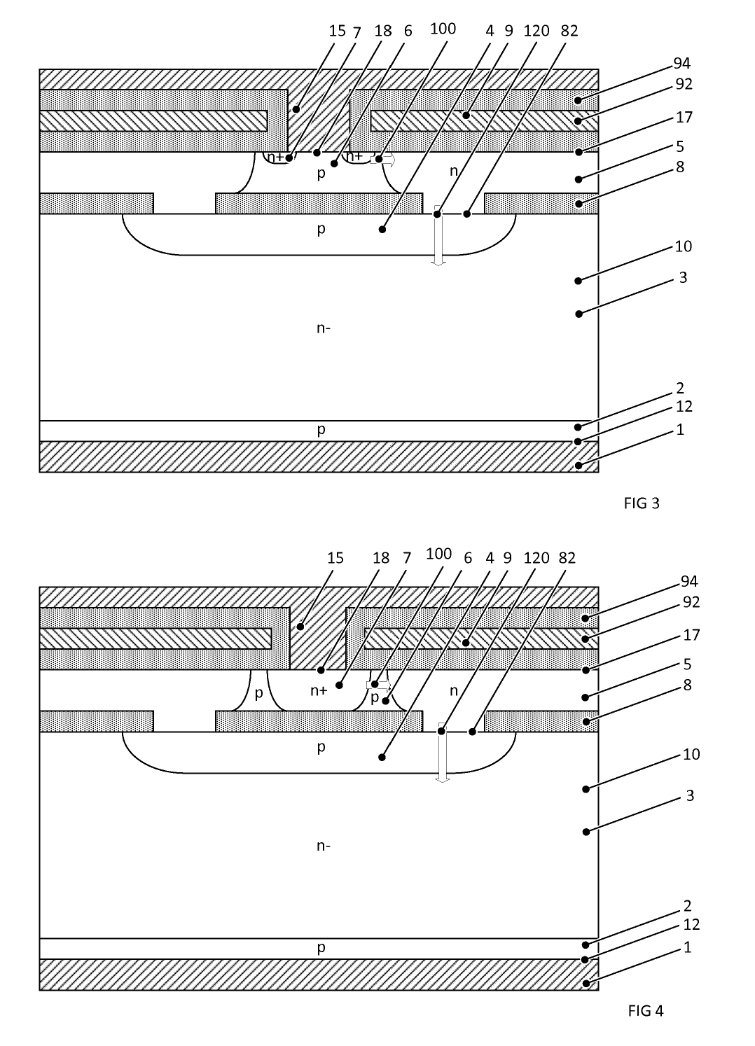

The body layer 6 may either be completely separated from the emitter electrode 15 by the source region 7 as shown in FIG. 2 or it may contact the emitter electrode 15 at the emitter contact opening 18 as shown in FIG. 3. The body layer 6 is arranged between the source region 7 and the emitter layer 5. The first insulating layer 8 laterally extends beyond the body layer 6. Therefore, there is neither a contact of the body layer 6 to the base layer 4 nor to the drift layer 3, i.e. it does not touch these layers. The first insulating layer 8 ensures this separation. In another inventive embodiment shown in FIG. 12 the device comprises a highly p+ doped body contact layer 62, which is arranged in between the emitter contact area 18 and the p doped body layer 6 in order to have a highly doped interlayer at the contact to the emitter electrode 15. The p+ body contact layer 62 may be limited to the area at which a p doped layer is in contact to the emitter electrode 15, i.e. at the emitter contact area 18.

The body contact layer 62 may have a maximum doping concentration between 5×10¹⁸/cm³ and 5×10¹⁹/cm³. The body contact layer 62 and body layer 6 may be formed as diffused layers, i.e. as overlaid layers, in which the doping concentration of each layer decreases in depth direction from the emitter side 17, but the body contact layer 62 is arranged up to a first depth, which is smaller than the maximum depth of the body layer 6 (measured from the emitter side 17). The body contact and body layer 62, 6 overlap such that at the cross point a discontinuous decrease of the doping concentration is present.

The maximum doping concentration of the body layer 6 may be lower than the maximum doping concentration of the first layer 65 and/or the source region 7. The maximum doping concentration of the body layer 6 may be a factor of 10 to 100 below the maximum doping concentration of the source region 7 (and/or first layer 65). Also the maximum doping concentration of a second layer 55 may be in such a range. In an exemplary embodiment, the maximum doping concentration of the body layer 6 and/or second layer 55 (which is explained below in more details) may be between 10¹⁶ and 10¹⁸ cm⁻³.

The maximum doping concentration of the base layer 4 may be in the same range as of the body layer 6, i.e. the maximum doping concentration of the base layer 4 may be a factor of 10 to 100 below the maximum doping concentration of the source region 7 (or the first layer) and/or the maximum doping concentration of the base layer 4 may be between 10¹⁶ and 10¹⁸ cm⁻³. Base layer 4 and body layer 6 are completely separated from each other by at least one of the first insulating layer 8 or the emitter layer 5 (i.e. by an n doped layer).

The source region 7 may be a shallow region, which is embedded towards the collector side 12 in the body layer 6. Alternatively, the source region 7 may extend from the emitter side 17 to the first insulating layer 8 as shown in FIG. 4. The source region 7 is separated by the first insulating layer 8 from the base layer 4 and by the body layer 6 from the emitter layer 5. The maximum doping concentration of the source region 7 may be between 10¹⁸ and 10²⁰ cm⁻³. The maximum doping concentration of a first layer 65 (which is explained below in more details) may be in the same range, i.e. between 10¹⁸ and 10²⁰ cm′.

The emitter layer 5 exemplarily extends from the emitter side 17 to the first insulating layer 8. It is in contact to the base layer 4 at the opening 82. The first insulating layer 8 and the opening 82 limit the extension of the emitter layer 5 in depth direction, i.e. in a direction perpendicular to the emitter side 17.

In an exemplary embodiment, the maximum doping concentration of the emitter layer 5 may be lower than that of the source region in a range between 10¹⁷ cm⁻³ to a value smaller than 10²⁰ cm⁻³, or between 10¹⁸ and 10¹⁹ cm⁻³. Source region 7 and emitter layer 5 are completely separated from each other by the body layer 6.

The emitter layer 5 is separated from the source region 7 by the body layer 6, and from the drift layer 3 by the base layer 4. Thus, the emitter layer 5 separates the body layer 6 from the base layer 4.

The first insulating layer 8 may have a thickness of 0.1 to 0.5 μm. It may extend up to a maximum depth from the emitter side 17 (e.g. from the contact area 18 of the emitter electrode 15) of 1.0 to 5.0 μm The first insulating layer 8 is arranged below (i.e. in a depth from the emitter side 17 greater than layers mentioned in the following) the source region 7, the emitter layer 5, the body layer 6 and, if present the body contact layer 62. The base layer 4 may be arranged in an area solely below the first insulating layer 8. Alternatively, the first insulating layer 8 may be surrounded by the base layer 4 laterally and in depth direction.

Exemplarily, the drift layer 3 has a constantly low doping concentration. Therein, the substantially constant doping concentration of the drift layer 3 means that the doping concentration is substantially homogeneous throughout the drift layer 3, however without excluding that fluctuations in the doping concentration within the drift layer being in the order of a factor of one to five may be possibly present due to e.g. a manufacturing process of the wafer being used. An exemplary doping concentration of the drift layer 3 is between 2*10¹² cm⁻³ and 1.5*10¹⁴ cm⁻³.

Exemplarily, towards the collector side 12, the base layer 4 only contacts the drift layer 3, i.e. there is no higher n doped enhancement layer arranged between the base and drift layer 3, 4, which completely separates the lowly doped drift layer 3 and the p doped base layer 4.

In an exemplary embodiment, there is an n doped buffer layer arranged between the drift layer 3 and the collector layer 2, which has higher doping concentration than the drift layer 3. Exemplarily, the buffer layer is a diffused layer, which means that the doping concentration within the layer rises constantly in direction towards the collector side 12 up to a maximum doping concentration of the layer.

In another exemplary embodiment, the inventive semiconductor device is formed as a reverse conducting device, which comprises in the plane of the collector layer 2 and alternating with the collector layer 2 a highly doped n layer, which also contacts the collector electrode 1. Exemplarily, each of the collector layer 2 and the n doped layer comprises regions, which are arranged in a regular manner, i.e. n and p doped regions alternate.

The inventive semiconductor device comprises an additional hole path, in which holes can flow to the emitter electrode 15 during turn-off of the device. Such a hole path may be integrated on one side of an emitter contact opening 18 having the inventive MIS and first thyristor channel structure on an opposite side of the emitter contact opening 18. Such structures are shown in the FIGS. 5 to 9 on the left hand side of the figures. As shown in FIGS. 5 to 9, such a hole path cell may be achieved by the integration of a p-MIS channel 110, which comprises a highly doped p+ first layer 65, which is in contact to the emitter electrode 15 at the emitter contact opening 18.

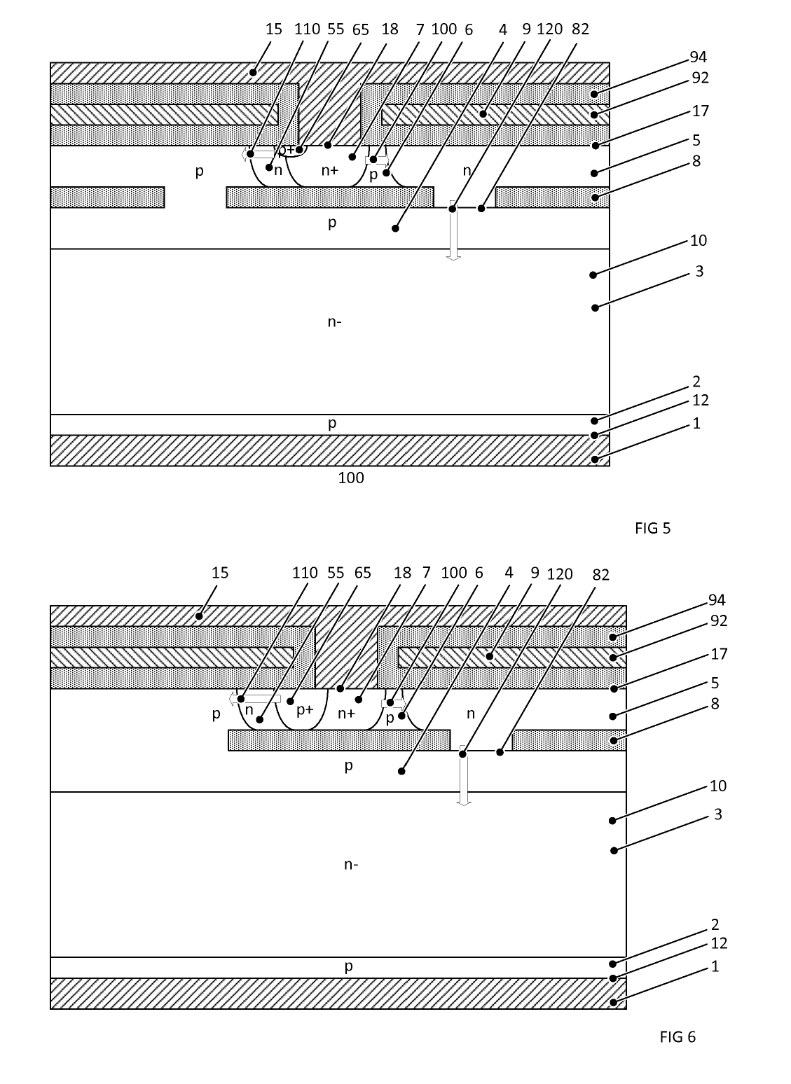

The first layer 65 extends to an area below the gate electrode 9. Between the first layer 65 and the base layer 4, an n doped second layer 55 is arranged, which separates both p doped layers 65, 4. A P MIS channel 110 is, thus formable, between the p+ doped first layer 65, the n doped second layer 55 and the p doped base layer 4 (which is arranged below the same planer gate electrode 9 such that a MIS channel 110 is formable). Like the source region 7, the first layer 65 may either be a shallow layer, embedded towards the collector side 12 in an n doped layer (the source region 7 and/or the second layer 55) as shown in FIG. 5 or it may extend from the emitter side 17 to the first insulating layer 8 as shown in FIG. 6. In this case, the second layer 55 is separated from the source region 7, in the case of a shallow second layer 55, it is in contact to the source region 7. In any case, the second layer 55 is an n doped layer, which is separated from the emitter layer 5. These hole path cells extend in a plane parallel to the emitter side 17 in an area, in which the P MIS channel 110 is formable. The p body contact layer 62 differs from the first layer 65 in that the p body contact layer 62 improves the contact between body layer 6 and emitter electrode 15 and is therefore arranged such that the emitter electrode 15 is in contact to a p doped layer only through the highly doped body contact layer 62. The first layer 65 is arranged in contact to the emitter electrode 15 to a region below the planar gate electrode 9 so that a MIS channel 110 is formable. Of course, a highly doped p layer could be arranged from a region below the planar gate electrode 9 along the contact area to the emitter electrode 15 such that this layer is a common layer which functions as a body contact layer in the central part and as a first layer on the peripheral part of the common layer.

As already mentioned before, the source region 7 may extend from the emitter side 17 to the first insulating layer 8 as shown in the FIGS. 5 and 6 (like in FIG. 4) or the source region 7 may be a shallow region, which is embedded towards the collector side 12 in the body layer 6.

For a shallow source region 7, the body layer 6 may either be completely separated from the emitter electrode 15 by the source region 7 (like in FIG. 2 with the exception that for an inventive device having an integrated hole path the p+ first layer also contacts the emitter electrode 15) or it may contact the emitter electrode 15 at the emitter contact opening 18 as shown in FIG. 8 (like in FIG. 3). For such a device, also the body layer 6 contacts the emitter electrode 15.

It is possible that at one emitter contact opening an n-MIS channel 100 and a p-MIS channel 110, in which holes flow between the first layer 65 through the second layer 55 to the base layer 4, are present at the opening 18 (as shown in the FIGS. 5 to 8).

Alternatively, at one emitter contact opening 18 only n-MIS channels 100 are present, i.e. no p MIS channels are present (as shown in FIGS. 2 to 4) and at another emitter contact opening 18 only p-MIS channels (turn-off channels) 110 are present (as shown in FIG. 9). FIG. 9 shows exemplarily such an emitter contact, at which only p MIS channels 110 are present (i.e. no turn-off channels). The p MIS channel 110 is similar to that shown in FIG. 6 on the left hand side of the emitter contact opening 18, but in FIG. 9 such a p MIS channel is present also on the right hand side of the emitter contact opening 18. Of course, any p MIS channel 110 design like those shown in the FIGS. 5 to 8 can be used at an emitter contact area 18 having purely p MIS channels.

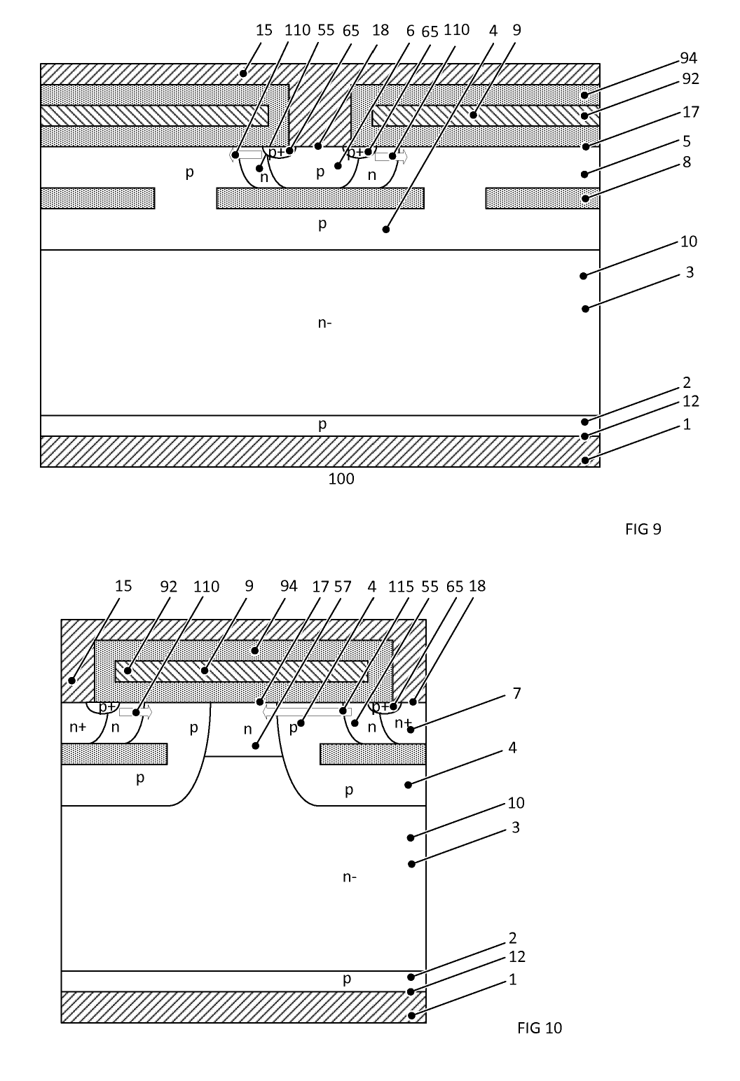

In addition to the structures shown in FIGS. 5 and 6, the inventive semiconductor device may comprise a turn-on cell in order to turn on the device. FIG. 10 shows the integration of a turn-on cell by having an electron path structure (n MIS channel 115, in which electrons flow from the second layer 55 through the base layer 4 to the drift layer 3 or an n doped fourth layer 57. At the lateral side of the base layer 4 the n doped fourth layer 57 may be arranged, which extends to the first main side 17 and which is higher doped than the drift layer 3. Thus, the base layer 4 terminates at the fourth layer 57. Exemplarily, the fourth layer 57 is arranged between two base layers 4, at which base layers 4 n MIS channels 115 are formable at the surface (emitter side 17), which channels 110 are directed to different emitter contact openings 18. In depth direction, the fourth layer 57 is arranged below the gate electrode 9 and above the drift layer 3. The fourth layer 57 is in contact to the drift layer 3. By the arrangement of the fourth layer 57 between two neighboured base layers 4 the JFET effect diminishes and the space required for the integrated turn-on cell can be kept small. The fourth layer 57 may have a doping concentration in a range from 1*10¹⁴ cm⁻³ up to 5*10¹⁶ cm⁻³. In an exemplary embodiment, the fourth layer 57 has a lower maximum doping concentration than the second layer 55. Alternatively, the fourth layer 57 may also be equally doped as the second layer 55 or even higher doped.

Alternatively, the fourth layer 57 can be omitted, so that the drift layer 3 reaches the emitter side 17 in between neighboring p base layers 4. This may exemplarily be advantageously be applied for higher values of doping concentration of the drift layer 3.

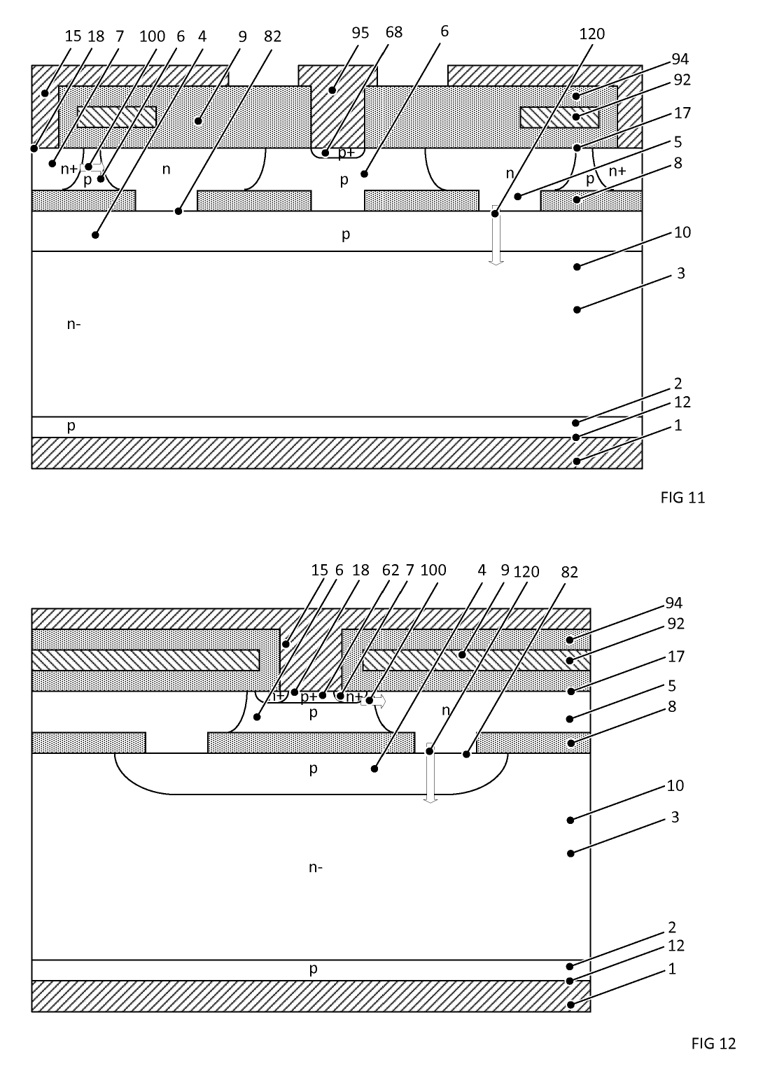

FIG. 11 shows another turn-on cell, which is arranged laterally to the inventive structure of MIS channel 100 and thyristor paths 120. The device comprises a turn-on cell with a turn-on gate electrode 95, which is a separate electrode from the planar gate electrode 9 and the emitter electrode 15 as shown, e.g. in FIG. 5 or 6. Such turn-on cells are known from prior art GTOs. The turn-on gate electrode 95, which is also a planar gate electrode, is arranged laterally to the emitter electrode 15 and the planar gate electrode 9. It comprises an electrically conductive layer, which is insulated from the emitter electrode 15 and the planar gate electrode 9 by the second insulating layer 94. The electrically conductive layer of the turn-on gate electrode 95 contacts in the wafer only a p doped third layer 68, which has a higher maximum doping concentration than the base layer 4, exemplarily in a range of 1*10¹⁸ cm⁻³ up to 1*10²⁰ cm⁻³.

According to FIG. 11, turn-on is accomplished when positive voltages are applied simultaneously to the gate electrode 9 (n MIS channel 100 active) and to the turn-on electrode 95. Turn-on will proceed in the classical manner known from for example GTOs. Once the thyristor is turned on, gate bias from gate electrode 95 can be withdrawn. Turn-off is accomplished applying negative bias to gate electrode 92 (p MIS channel 110 active). The turn-off action can be increased by applying negative bias to electrode 95 as well.

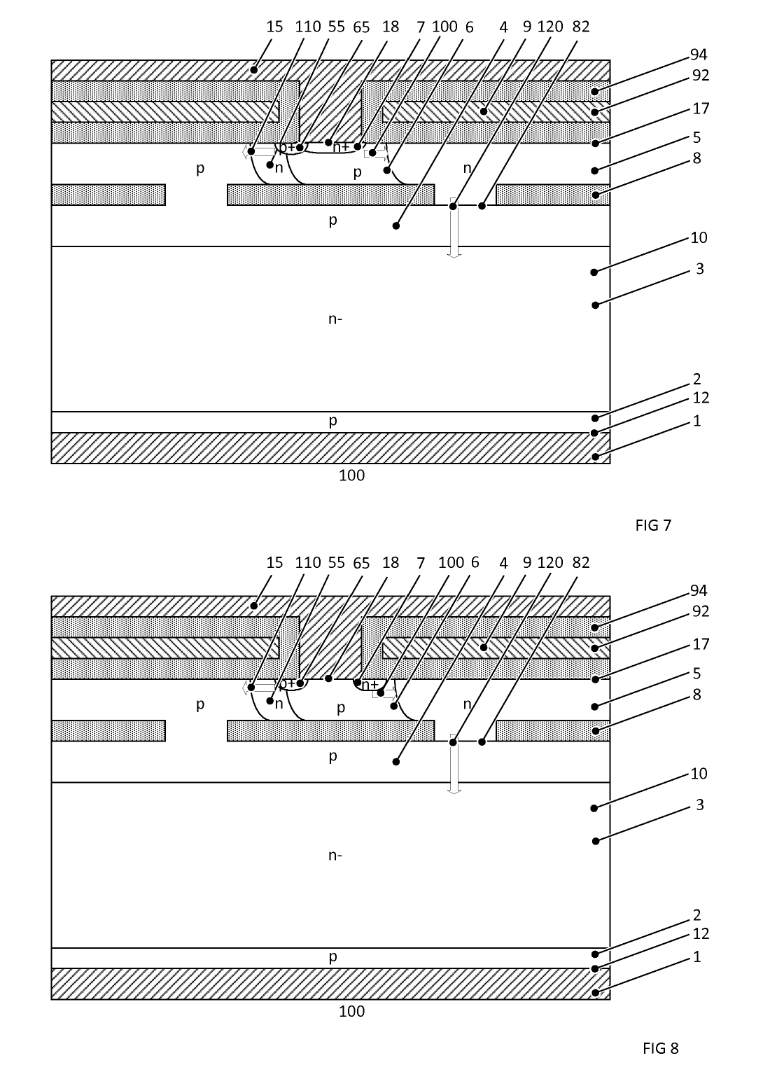

Thus, in the embodiments shown in FIG. 5 or 6 and in addition with the turn-on channels as shown in the FIG. 7 or 8, the inventive semiconductor device comprises a turn-on cell in order to turn on the device, which may be integrated at the same emitter contact opening 18 (like in FIG. 10) or as a separate area using a separate electrode in the device (like in FIG. 11).

A turn-off cell is formed in an area, in which the n-MIS channel 100 and first thyristor paths 120 are formable. The total area occupied by the turn-on cells may be between 1 and 50% of the total area occupied by the turn-off cells.

A power semiconductor module may be formed by a plurality of semiconductor devices (i.e. at least two) according to the invention, which may be arranged on a common or separate wafer. The devices are exemplarily arranged in a regular manner. For a module with a plurality of devices, the turn-on cells may be arranged in a regular manner over the device area, but it is also possible that they are arranged at the border of the active area, between the turn-off cells and the termination area of the module. The module may be terminated by termination means, which are well-known to the persons skilled in the art. Any other arrangement of the turn-on cells is also possible like arranging them in the central part of the module.

In another embodiment, the conductivity types are switched, i.e. all layers of the first conductivity type are p type (e.g. the drift layer 3) and all layers of the second conductivity type are n type (e.g. base layer 4).

It should be noted that the term “comprising” does not exclude other elements or steps and that the indefinite article “a” or “an” does not exclude the plural. Also elements described in association with different embodiments may be combined. It should also be noted that reference signs in the claims shall not be construed as limiting the scope of the claims. The term “at least one of A or B” shall cover the meaning that at least A is present or B is present or A and B is present.

### REFERENCE LIST

1 collector electrode
12 collector side
15 emitter electrode
17 emitter side
18 emitter contact area
2 collector layer
3 drift layer
4 base layer
42 base contact layer
5 emitter layer
55 second layer
57 fourth layer
6 body layer
62 body contact layer
65 first layer
68 third layer
7 source region
72 further source region
8 first insulating layer
82 opening
9 planar gate electrode
92 gate layer
93 further gate layer
94 second electrically insulating layer
95 turn-on gate electrode
100 n MIS channel
105 thyristor current path
110 p MIS channel
120 first thyristor current path
140 second thyristor current path

1.-14. (canceled)

15. A power semiconductor device comprising, in the following order:
a collector electrode,
a collector layer of a second conductivity type,
a drift layer of a first conductivity type,
a base layer of the second conductivity type,
a first insulating layer having an opening,
an emitter layer of the first conductivity type, wherein the emitter layer is in contact to the base layer and wherein the emitter layer is separated from the drift layer at least by one of the first insulating layer or the base layer,
a body layer of the second conductivity type, which is arranged laterally to the emitter layer and which body layer is separated from the base layer by the first insulating layer and the emitter layer,
a source region of the first conductivity type, which is separated from the emitter layer by the body layer,
an emitter electrode, which is contacted by the source region,
wherein the device further comprises a first layer of the second conductivity type, which is in contact to the emitter electrode and separated from the base layer, and a second layer of the first conductivity type, which is arranged between the first layer and the base layer wherein the body layer is arranged between the second layer and the emitter layer,
wherein a planar gate electrode is arranged laterally from the emitter electrode, which planar gate electrode comprises an electrically conductive gate layer and a second insulating layer, which insulates the gate layer from any layer of the first or second conductivity type and from the emitter electrode,
wherein a MIS channel is formable below the planar gate electrode in the body layer between the source region and the emitter layer,
wherein a first thyristor current path is formable below the planar gate electrode between the emitter layer, the base layer and the drift layer through the opening, and
wherein a turn-off MIS channel is formable below the planar gate electrode in the second layer between the first layer and the base layer to the drift layer.

16. The power semiconductor device according to claim 15, wherein the body layer is separated from the emitter electrode by the source region.

17. The power semiconductor device according to claim 15, wherein the body layer contacts the emitter electrode.

18. The power semiconductor device according to claim 15, wherein the source region extends to the first insulating layer.

19. The power semiconductor device according to claim 15, wherein the device comprises a turn-on gate electrode, which is arranged laterally to the emitter electrode and the planar gate electrode and which turn-on gate electrode comprises an electrically conductive layer, which is insulated from the emitter electrode and the planar gate electrode by the second insulating layer.

20. The power semiconductor device according to claim 15, wherein the maximum doping concentration of at least one of the first layer or the source region is between 10¹⁸ and 10²⁰ cm⁻³.

21. The power semiconductor device according to claim 15, wherein the maximum doping concentration of the emitter layer is between 10¹⁷ and 10²⁰ cm⁻³, or between 10¹⁸ and 10¹⁹ cm⁻³.

22. The power semiconductor device according to claim 15, wherein the maximum doping concentration of at least one of the body layer or the second layer is a factor of 10 to 100 below the maximum doping concentration of the source region.

23. The power semiconductor device according to claim 15, wherein the maximum doping concentration of at least one of the body layer or the second layer is between 10¹⁶ and 10¹⁸ cm⁻³.

24. The power semiconductor device according to claim 22, wherein the maximum doping concentration of the base layer is in the same range as of the body layer.

25. The power semiconductor device according to claim 23, wherein the maximum doping concentration of the base layer is in the same range as of the body layer.

26. The power semiconductor device according to claim 15, wherein the first insulating layer is arranged up to a maximum depth of 1.0 to 5.0 μm below an emitter contact area of the emitter electrode to the source region.

27. The power semiconductor device according to claim 15, wherein the second insulating layer has a thickness of 0.05 to 0.2 μm in an area, in which the second insulating layer is arranged between the gate layer and the wafer.

28. The power semiconductor device according to claim 15, wherein the MIS channel and the turn-off MIS channel are formable at the same emitter contact opening, at which the source region and the first layer contact the emitter electrode.

29. The power semiconductor device according to claim 15, wherein the device comprises an emitter electrode contact opening, at which only a MIS channel is formable and another emitter electrode contact opening, at which only a turn-off MIS channel is formable.

30. The power semiconductor device according to claim 16, wherein the device comprises a turn-on gate electrode, which is arranged laterally to the emitter electrode and the planar gate electrode and which turn-on gate electrode comprises an electrically conductive layer, which is insulated from the emitter electrode and the planar gate electrode by the second insulating layer.

31. The power semiconductor device according to claim 17, wherein the device comprises a turn-on gate electrode, which is arranged laterally to the emitter electrode and the planar gate electrode and which turn-on gate electrode comprises an electrically conductive layer, which is insulated from the emitter electrode and the planar gate electrode by the second insulating layer.

32. The power semiconductor device according to claim 16, wherein the MIS channel and the turn-off MIS channel are formable at the same emitter contact opening, at which the source region and the first layer contact the emitter electrode.

33. The power semiconductor device according to claim 17, wherein the MIS channel and the turn-off MIS channel are formable at the same emitter contact opening, at which the source region and the first layer contact the emitter electrode.

34. The power semiconductor device according to claim 16, wherein the device comprises an emitter electrode contact opening, at which only a MIS channel is formable and another emitter electrode contact opening, at which only a turn-off MIS channel is formable.

35. The power semiconductor device according to claim 17, wherein the device comprises an emitter electrode contact opening, at which only a MIS channel is formable and another emitter electrode contact opening, at which only a turn-off MIS channel is formable.
